(19) United States
(12) Patent Application Publication
(10) Pub. No.: US 2017/0181308 A1
(43) Pub. Date: Jun. 22, 2017

(54) ELECTRONIC UNIT HOLD DOWN ASSEMBLY

(71) Applicant: TYCO ELECTRONICS CORPORATION, Berwyn, PA (US)

(72) Inventors: Nicholas John Swatko, Mountain View, CA (US); Paul Craig Tally, Santa Clara, CA (US); Roenna Nepomuceno del Rosario, Union City, CA (US); David A. Hurrell, San Mateo, CA (US)

(21) Appl. No.: 15/060,210

(22) Filed: Mar. 3, 2016

Related U.S. Application Data
(60) Provisional application No. 62/268,306, filed on Dec. 16, 2015.

(51) Int. Cl. H05K 7/14; B64D 47/00

(52) U.S. Cl. CPC H05K 7/1412; B64D 47/00

(57) ABSTRACT

A hold down assembly for an electronic unit includes a locking washer having a cone at a front end thereof. The locking washer has a tang provided in the cone and extending forward from the cone. The cone is configured to receive a mounting hook of the electronic unit with a first side of the tang bearing against the mounting hook to lock the position of the locking washer relative to the mounting hook. An actuator knob is rotatably coupled to the locking washer. The actuator knob is configured to be tightened to a threaded shaft to tighten the hold down assembly to the electronic unit and drive the locking washer toward the mounting hook.

### CROSS REFERENCE TO RELATED APPLICATIONS

This application claims the benefit of U.S. Provisional Application No. 62/268,306 filed Dec. 16, 2015 titled ELECTRONIC UNIT HOLD DOWN ASSEMBLY, the subject matter of which is herein incorporated by reference in its entirety.

### BACKGROUND OF THE INVENTION

The subject matter herein relates generally to hold down assemblies.

Electronic units are typically held in equipment mounting trays. For example, in an aircraft, a plurality of electronic units are often mounted or stored in an avionics bay or rack. Other applications, such as data communication servers, have electronic units held in equipment mounting trays known as server racks. While some electronic units are permanently mounted within the trays, other electronic units may be portable such that the units can be removed from the bay and transported. The electronic units may be operatively connected to a supply of power and plugged into a communication or control system. The equipment mounting trays include a support structure for holding the electronic unit and may include a mating wire harness or plug for plugging the electronic unit into the system and enabling communication between the electronic unit and the system.

Hold down assemblies may be provided on the equipment mounting tray to secure the electronic unit in the tray. The hold down assembly includes a locking component that engages with a portion of a housing or bracket of the electronic unit. The locking component applies a force to the electronic unit to secure the electronic unit therein. However, hold down assemblies are not without disadvantages. For instance, in some applications, such as in avionics, the environment provides various vibration, shaking, and other similar forces on the units. This vibration can force conventional hold down assemblies to loosen from engagement with the electronic unit. The electronic unit can then become disengaged with the mating wire harness, thereby affecting the proper operation of the equipment. Anti-rotation features are used on hold down assemblies to resist loosening of the hold down assembly. For example, some hold down assemblies include ratcheting features for anti-rotation; however, the ratcheting features are subject to wear and make assembly time consuming. Moreover, some hold down assemblies are complex and include multiple pieces, making assembly time consuming and difficult. Furthermore, in some applications, such as avionics, weight or all components in the aircraft is a concern.

### BRIEF SUMMARY OF THE INVENTION

In one embodiment, a hold down assembly for an electronic unit includes a locking washer having a cone at a front end thereof. The locking washer has a tang provided in the cone and extending forward from the cone. The cone is configured to receive a mounting hook of the electronic unit with a first side of the tang bearing against the mounting hook to lock the position of the locking washer relative to the mounting hook. An actuator knob is rotatably coupled to the locking washer. The actuator knob is configured to be tightened to a threaded shaft to tighten the hold down assembly to the electronic unit and drive the locking washer toward the mounting hook.

In another embodiment, a hold down assembly for an electronic unit includes a locking washer having a cone at a front end thereof. The cone is configured to receive a mounting hook of the electronic unit to lock the position of the locking washer relative to the mounting hook. The hold down assembly includes a locking mechanism for locking the locking washer to the mounting hook. The locking mechanism has a ball bearing and a ratchet plate operably receiving the ball bearing. The ball bearing is ratcheted with the ratchet plate to lock the locking washer to the mounting hook. The hold down assembly includes an actuator knob receiving the locking mechanism and the locking washer. The actuator knob is rotatably coupled to the locking washer. The actuator knob causes the locking mechanism to ratchet to a locked position. The actuator knob is configured to be tightened to a threaded shaft to tighten the hold down assembly to the electronic unit and drive the locking washer toward the mounting hook. The actuator knob, locking mechanism and locking washer are freely rotatable about the shaft until the locking washer engages the mounting hook. The locking mechanism ratchets after the locking washer engages the mounting hook as the actuator knob is further tightened.

In a further embodiment, a hold down assembly for an electronic unit includes a locking washer having a base and a cone. The cone is configured to receive a mounting hook of the electronic unit to lock the position of the locking washer relative to the mounting hook. The base has detent holes therein. The hold down assembly includes a locking mechanism for locking the locking washer to the mounting hook. The locking mechanism has a ball bearing and a ratchet plate having a detent hole receiving the ball bearing. The hold down assembly includes an actuator knob receiving the locking mechanism and the locking washer with the ball bearing positioned between the ratchet plate and the base of the locking washer. The ratchet plate is fixed to the actuator knob and rotates with the actuator knob. The actuator knob is rotatably coupled to the locking washer to cause the ball bearing to successively ratchet between the detent holes of the locking washer.

### BRIEF DESCRIPTION OF THE DRAWINGS

FIG. 1 is a side view of a hold down assembly in accordance with an exemplary embodiment for retaining a portable electronic unit within an equipment mounting tray.

FIGS. 2 and 3 are front perspective views of the hold down device in accordance with an exemplary embodiment.

FIG. 4 is a front perspective, exploded view of the hold down device.

FIG. 5 is a rear perspective, exploded view of the hold down device.

FIG. 6 is a cross-sectional, exploded view of the hold down device.

FIG. 7 is an exploded, partial sectional view of the hold down device.

FIG. 8 is a front perspective, partial sectional view of the hold down device in an assembled state.

FIG. 9 is a cross-sectional view of the hold down device in an assembled state.

FIG. 10 is a rear perspective view of the hold down assembly showing the hold down devices attached to corresponding shafts and engaging corresponding mounting hooks.

FIG. 11 is a front perspective view of the hold down assembly showing the hold down devices attached to corresponding shafts and engaging corresponding mounting hooks.

FIG. 12 is a cross sectional view of the hold down assembly showing the hold down device attached to the corresponding shaft and engaging the corresponding mounting hook.

FIG. 13 is a front exploded view of a hold down assembly in accordance with an exemplary embodiment.

FIG. 14 is a rear exploded view of a hold down assembly shown in FIG. 13.

FIG. 15 is a cross-sectional view of the hold down device shown in FIG. 13 in an assembled state.

FIG. 16 is a rear exploded view of a hold down assembly in accordance with an exemplary embodiment.

FIG. 17 is a front exploded view of a hold down assembly shown in FIG. 16.

FIG. 18 is a cross-sectional view of the hold down device shown in FIG. 16 in an assembled state.

### DETAILED DESCRIPTION OF SPECIFIC EMBODIMENTS OF THE INVENTION

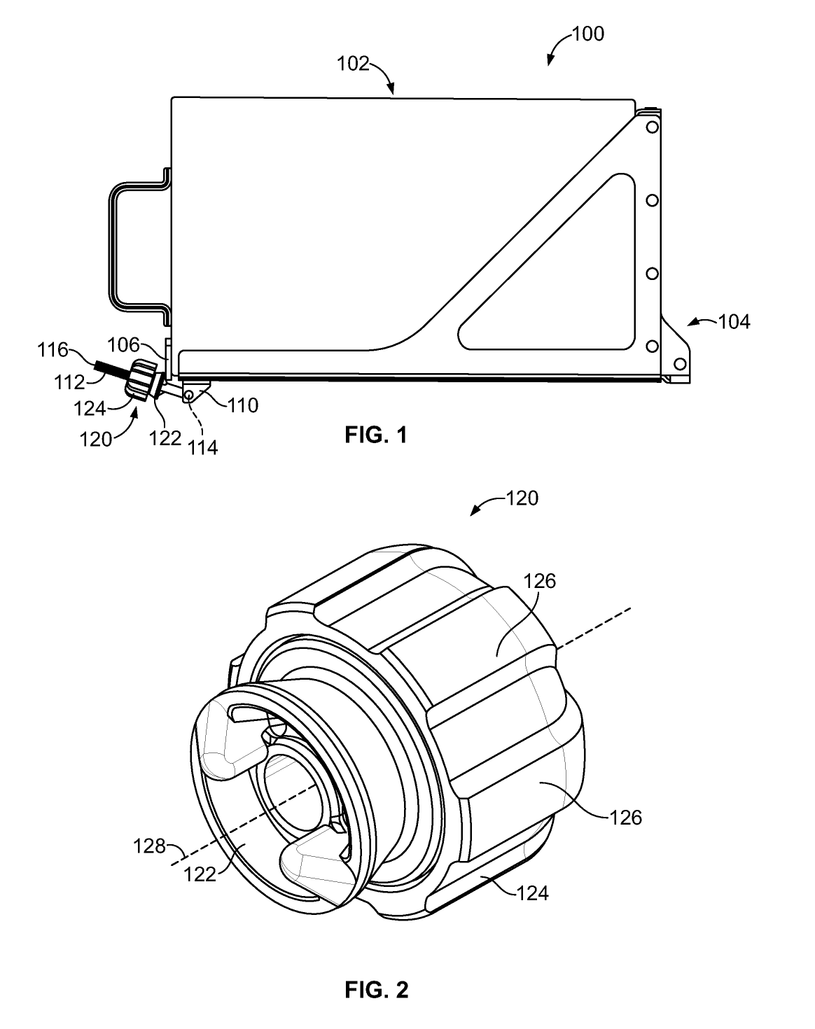

FIG. 1 is a side view of a hold down assembly 100 for retaining a portable electronic unit 102 within an equipment mounting tray 104. The equipment mounting tray 104 may be an avionics equipment mounting tray 104 in various embodiments; however the hold down assembly 100 is not limited to such applications. The electronic unit 102 includes a mounting hook 106, which may extend from a portion of the electronic unit 102, such as a side of the electronic unit 102. The mounting hook 106 may be an L-shaped hook (also known as a J-hook); however the mounting hook 106 may have other shapes or features in alternative embodiments. The mounting hook 106 may be integral to the electronic unit 102, such as part of the case or housing of the electronic unit 102, or alternatively may be secured, such as using fasteners, to the electronic unit 102. The hold down assembly 100 may engage and lock to the mounting hook 106 to secure the electronic unit 102 to the equipment mounting tray 104.

The hold down assembly 100 includes a hinge block 110 coupled to the equipment mounting tray 104 and a shaft 112 coupled to the hinge block 110. The shaft 112 may pivot about the hinge block 110. The shaft 112 extends between a first end 114 adjacent to the hinge block 110 and a second end 116 opposite the first end 114. The first end 114 may be pivotably coupled to the hinge block 110, such as about a pin, rivet or other component. In an exemplary embodiment, the shaft is a threaded shaft 112. Optionally, the shaft 112 has a circular cross section with external threads. Alternatively, the shaft 112 may include a non-circular cross section such as a D-cross-section having a curved portion and a flattened portion or a double-D cross section having two opposing curved portions and two opposing flattened portions.

The hold down assembly 100 includes a hold down device 120 coupled to the shaft 112. For example, the hold down device 120 may be threadably coupled to the shaft 112. The hold down device 120 includes a locking washer 122 and an actuator knob 124 operably coupled to the shaft 112. The locking washer 122 engages the mounting hook 106. For example, a portion of the mounting hook 106 may be received in the locking washer 122. During assembly, the actuator knob 124 is rotated about the shaft 112 to drive the locking washer 122 axially along the shaft 112 into the mounting hook 106. The actuator knob 124 then applies a locking force on the locking washer 122, which locks the hold down device 120 to the mounting hook 106 to hold the portable electronic unit 102 in position on or in the equipment mounting tray 104. In an exemplary embodiment, the hold down device 120 includes a locking mechanism to lock the locking washer 122 in place and resist loosening over time, such as from vibration.

In an exemplary embodiment, the portable electronic unit 102 may be a line-replaceable unit (LRU) of an airplane; however, the unit may be may be any other type of modular component or other manufactured device that is designed to be replaceable within the equipment mounting tray 104. The portable electronic unit 102 may have electrical power and/or data-transferring connectors, sockets, plugs, cables and the like extending therefrom. The equipment mounting tray 104 may include mating connectors or a mating wire harness configured for mating with the electronic unit 102 when the portable electronic unit 102 is locked into the equipment mounting tray 104. The hold down assembly 100 ensures that the portable electronic unit 102 stays in operative contact with the mating wire harness and the other electronic equipment.

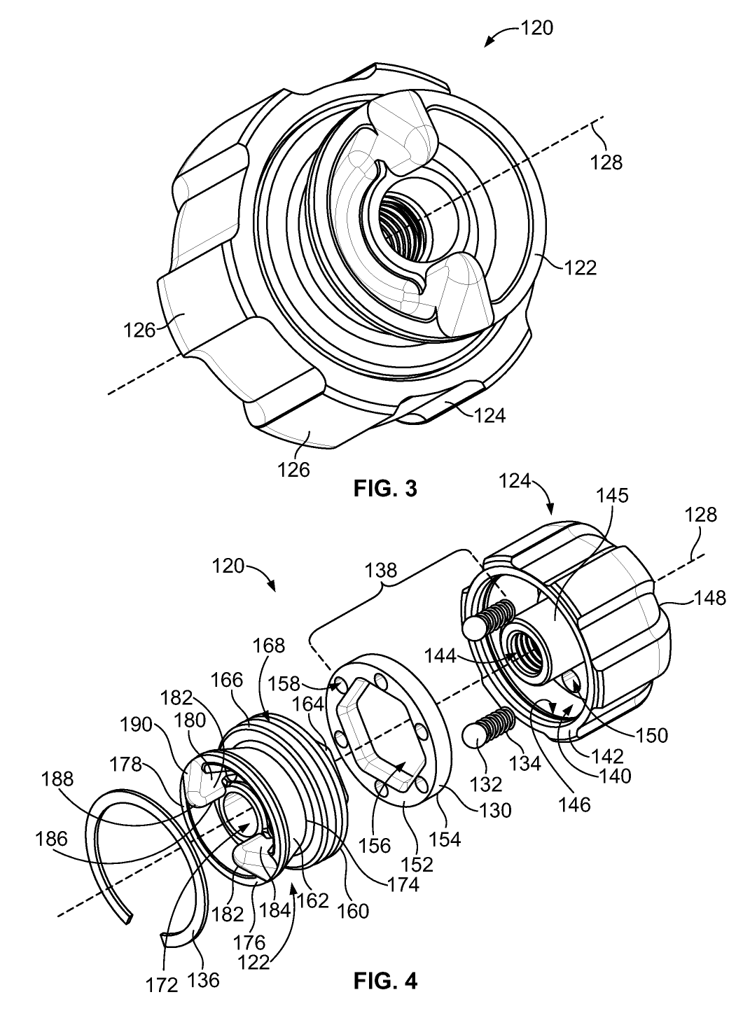

FIGS. 2 and 3 are front perspective views of the hold down device 120 in accordance with an exemplary embodiment. The actuator knob 124 is coupled to the locking washer 122 and may be secured thereto to provide a unitary hold down device 120. Optionally, a portion of the locking washer 122 may be received in the actuator knob 124. A portion of the locking washer 122 may extend forward of the actuator knob 124. The actuator knob 124 is configured to be rotated to axially advance the hold down device 120 along the shaft 112 (shown in FIG. 1).

In an exemplary embodiment, the actuator knob 124 includes a plurality of protrusions 126 along the outer surface thereof. The protrusions 126 provide a gripping surface for the operator to rotate the actuator knob 124. Additionally or alternatively, the outer surface of the actuator knob 124 may be knurled to form a gripping surface for a user's hand to rotate the actuator knob 124. In an exemplary embodiment, the protrusions 126 are equally spaced apart about the exterior of the actuator knob 124 with gaps or spaces therebetween. Any number of protrusions 126 may be provided. In the illustrated embodiment, six protrusions 126 are provided being sized and spaced apart to allow a standard hexagonal socket to be operably attached thereto. The socket may be driven by a tool, such as a torque wrench, a torque gun or another type of tool used to rotate the actuator knob 124 for tightening or untightening the hold down device 120. The hold down device 120 may be tightened or untightened by rotating the actuator knob 124 about a longitudinal axis 128. The locking washer 122 may be centered about the longitudinal axis 128.

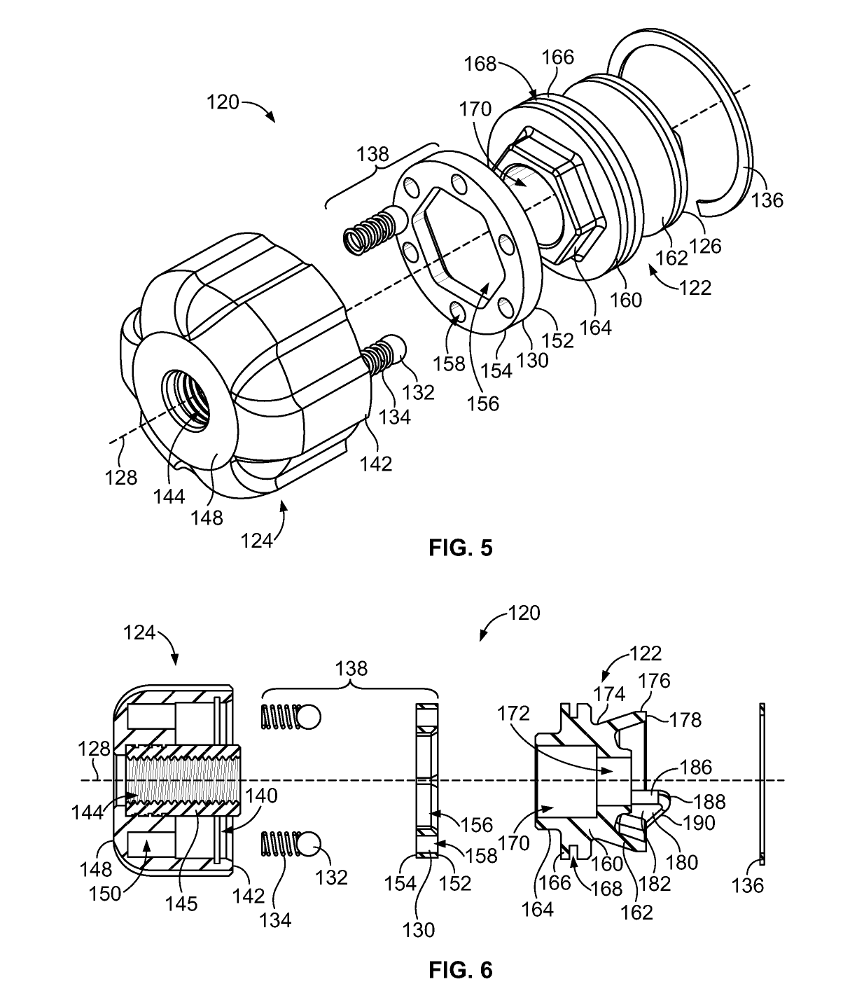

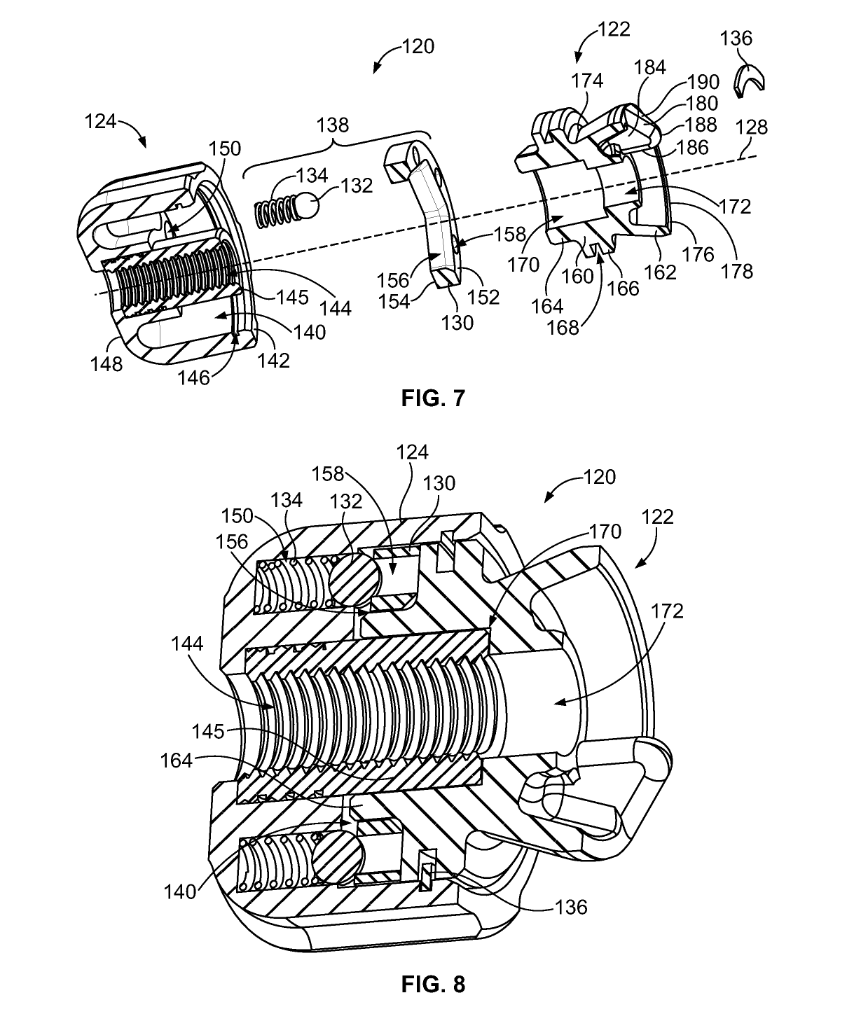

FIG. 4 is a front perspective, exploded view of the hold down device 120. FIG. 5 is a rear perspective, exploded view of the hold down device 120. FIG. 6 is a cross-sectional, exploded view of the hold down device 120. FIG. 7 is an exploded, partial sectional view of the hold down device 120. The hold down device 120 includes the locking washer 122, a ratchet plate 130, one or more ball bearings 132, one or more biasing members 134 and a clip 136 used to hold the locking washer 122, the ratchet plate 130, the ball bearings 132 and the biasing members 134 in the actuator knob 124. For example, the ratchet plate 130 is held within the actuator knob 124 by the locking washer 122 and corresponding clip 136. The ratchet plate 130 holds the ball bearings 132 and biasing members 134 in the actuator knob 124. The ratchet plate 130, ball bearings 132 and biasing members 134 may define a locking mechanism 138 of the hold down device 120 for locking the hold down device 120 to the mounting hook 106 to resist loosening or back-out over time.

The actuator knob 124 includes a cavity 140 configured to receive the ball bearings 132, the biasing members 134, the ratchet plate 130 and a portion of the locking washer 122. The cavity 140 is open at a front 142 of the actuator knob 124. In an exemplary embodiment, the actuator knob 124 includes a threaded bore 144 configured to be threadably coupled to the shaft 112 (shown in FIG. 1). Optionally, the threaded bore 144 may be part of an insert 145 separate from the actuator knob 124 that is coupled to the actuator knob 124. Optionally, the insert 145 may be a metal insert 145 including the threads defining the threaded bore 144. The insert 145 may be overmolded by the actuator knob 124. Alternatively, the insert 145 may be secured to the actuator knob 124, such as using adhesive, fasteners or other means. In other various embodiments, the threaded bore 144 is an integral part of the actuator knob 124 rather than a separate insert. For example, the threaded bore 144 may be molded with the actuator knob 124. In an exemplary embodiment, the actuator knob 124 is manufactured from a plastic material; however the actuator knob 124 may be manufactured from other materials, such as a metal material.

In an exemplary embodiment, the actuator knob 124 includes a circumferential groove 146 near the front 142. The groove 146 receives the clip 136 to hold the other components in the cavity 140. Alternatively, rather than using the clip 136 and corresponding groove 146, the front 142 of the actuator knob 124 may be pressed to form an inwardly-directed rolled edge at the front 142 that captures the locking washer 122 therein. The locking washer 122 may directly engage the rolled edge to restrict removal of the components. In either embodiment, the ratchet plate 130 and locking washer 122 are captured in and move longitudinally in unison with the actuator knob 124 along the shaft 112 when the actuator knob 124 is rotated. In an exemplary embodiment, a rear 148 of the actuator knob 124 closes the back side of the cavity 140 to capture the other components therein.

In an exemplary embodiment, the rear 148 includes pockets 150 that receive corresponding biasing members 134. In the illustrated embodiment, the biasing members 134 are coil springs; however, other types of biasing members 134 may be provided in alternative embodiments. Additionally, while two biasing members 134 and corresponding ball bearings 132 are illustrated, it is realized that any number of biasing members 134 and ball bearings 132, including a single biasing member 134 and/or a single ball bearing 132, may be provided in alternative embodiments.

The ratchet plate 130 includes a front 152 and a rear 154. Optionally, the ratchet plate 130 may be generally disk shaped. The ratchet plate 130 includes a central bore 156 extending therethrough. Optionally, the central bore 156 may be cylindrical. Alternatively, the central bore 156 may be polygonal shaped, such as hexagonal shaped. In other embodiments, the central bore 156 may have other shapes, such as a D shape or a double D shape having a single flat side or a pair of flat sides, respectively. Other shapes are possible in alternative embodiments. The shaft 112 is configured to pass through the bore 156. Optionally, the shaft 112 passes through the bore 156 without engaging the ratchet plate 130 such that the ratchet plate 130 is freely rotatable relative to the shaft 112. In an exemplary embodiment, the bore 156 receives a portion of the locking washer 122, which may lock the ratchet plate 130 to the locking washer 122. Optionally, the insert 145 of the actuator knob 124 may at least partially pass through the central bore 156. In an exemplary embodiment, the ratchet plate 130 includes a plurality of detent holes 158 disposed about the central bore 156. The detent holes 158 may extend at least partially through the ratchet plate 130 and may be provided in a circular pattern around the central bore 156. The detent holes 158 are configured to receive the ball bearings 132 when assembled to cause a ratcheting effect during assembly and/or a locking effect when the hold down device 120 is secured to the mounting hook 106.

The locking washer 122 includes a base 160 and a cone 162 opposite the base 160. The cone 162 is countersunk defining a tapered collar configured to receive and lock to the mounting hook 106 (shown in FIG. 1). The base 160 is configured to be received in the actuator knob 124. In an exemplary embodiment, the base 160 includes a hub 164 configured to be received in the central bore 156 of the ratchet plate 130. Optionally, the hub 164 may be locked in place relative to the ratchet plate 130 when received therein. For example, the hub 164 may have a complementary shape to the central bore 156.

The base 160 includes a flange 166 extending therefrom. The flange 166 includes a groove 168 that receives the clip 136. The flange 166 is sized and shaped to fit in the front end of the cavity 140. The flange 166 may abut against the interior surface of the actuator knob 124 within the cavity 140. The clip 136 is received in the groove 168 and the groove 146 to axially secure the locking washer 122 to the actuator knob 124. However, in an exemplary embodiment, the clip 136 does not restrict rotations such that the actuator knob 124 is rotatable relative to the locking washer 122. For example, the actuator knob 124 may be rotated about the clip 136.

In an exemplary embodiment, the base 160 includes a chamber 170 open at the rear end thereof. The chamber 170 is configured to receive the front end of the insert 145 of the actuator knob 124. The locking washer 122 includes a central bore 172, through the chamber 170 and through the cone 162, which receives the shaft 112. The central bore 172 passes through the base 160 and the cone 162. The bore 172 may be sized to approximately match the cross-section of the shaft 112. In the illustrated embodiment, the central bore 172 is cylindrical; however, other shapes are possible in alternative embodiments, such as a D shape or double D shape. The cylindrical bore allows the locking washer 122 to pass freely along the shaft 112 such that the locking washer 122 is rotatable relative to the shaft 112, whereas other shaped bores may limit rotation of the locking washer 122 relative to the shaft 112.

The cone 162 has a generally frusto-conical shape including a narrow side 174 at or near the base 160 and a wide side 176 at the front of the locking washer 122. The cone 162 includes a lip 178 at the wide side 176 thereof. The wide side 176 is configured to face the mounting hook 106. The cone 162 is hollow and defined by an inner surface to receive the mounting hook 106. The inner surface defines the conical shaped cavity that receives a portion of the mounting hook 106. By reducing the size of the cone 162 (for example, at the narrow side 174), the overall weight of the locking washer 122 may be reduced. In an exemplary embodiment, at the interior of the cone 162 at the narrow side 174, the cone 162 may be undercut defining grooves or channels, which may reduce the weight and may provide a space for receiving the mounting hook 106 when locked thereto. The grooves or channels may extend into the base 160.

In an exemplary embodiment, the cone 162 includes one or more tangs 180 projecting into the cone 162. In an exemplary embodiment, the tangs 180 extend forward of the lip 178 of the cone 162. In the illustrated embodiment, two tangs 180 are provided 180° apart from each other; however, any number and placement of the tangs 180 is possible in alternative embodiments. Each tang 180 includes a first side 182 and a second side 184 opposite the first side 182. An interior edge 186 extends between the first and second sides 182, 184 such that the first and second sides 182, 184 extend between an inner surface of the cone 162 and the interior edge 186. Optionally, the edges 186 of the tangs 180 may face each other across the bore 172. The edges 186 may extend generally parallel to the longitudinal axis 128. The tangs 180 extend to a tip 188. In an exemplary embodiment, the tip 188 is positioned forward of the lip 178. Optionally, the tip 188 may be curved or rounded to reduce binding or wedging against the mounting hook 106 during assembly. The tang 180 may include an angled outer wall 190 opposite the edge 186 extending between the tip 188 and the lip 178. The angled outer wall 190 provides structural support for the tang 180 to the tip 188 while reducing the overall size, and thus the weight, of the tang 180.

The sides 182 or 184 of the tangs 180 provide a large surface area for interfacing with the mounting hook 106. In an exemplary embodiment, the lip 178 is recessed behind the tips 188 of the tangs 180 to reduce the depth of the cone 162 from the base 160 to the lip 178 compared to conventional locking washers, which may reduce a significant amount of the weight of the locking washer 122. Having the tangs 180 extend beyond the lip 178 provides the interference surface for the mounting hook 106 while allowing removal of a large area of the cone 162 (for example, as compared to conventional cones that are deeper for mating with the mounting hook). Additionally, the tangs 180 extend into the interior of the cone 162 from the collar or perimeter wall of the cone 162, which better positions the locking washer 122 for interfacing with the mounting hook 106. For example, the first side 182 may be generally parallel with the edge of the mounting hook 106 to provide a stop or locking surface. The edge 186 may be positioned generally at the bore 172 with the first side 182 extending from the edge 186 (at the bore 172) back to the collar or perimeter wall of the cone 162.

FIG. 8 is a front perspective, partial sectional view of the hold down device 120 in an assembled state. FIG. 9 is a cross-sectional view of the hold down device 120 in an assembled state. When assembled, the biasing members 134 are received in corresponding pockets 150 of the actuator knob 124. The ball bearings 132 are provided at ends of the biasing members 134. The ratchet plate 130 is received in the cavity 140 forward of the ball bearings 132. The biasing members 134 bias the ball bearings 132 against the ratchet plate 130 into corresponding detent holes 158. The locking washer 122 is received in the cavity 140 at the front of the actuator knob 124. The hub 164 of the locking washer 122 is received in the central bore 156 of the ratchet plate 130. The insert 145 of the actuator knob 124 is received in the chamber 170 such that the threaded bore 144 is aligned with the bore 172. The locking washer 122 is secured to the actuator knob 124 using the clip 136.

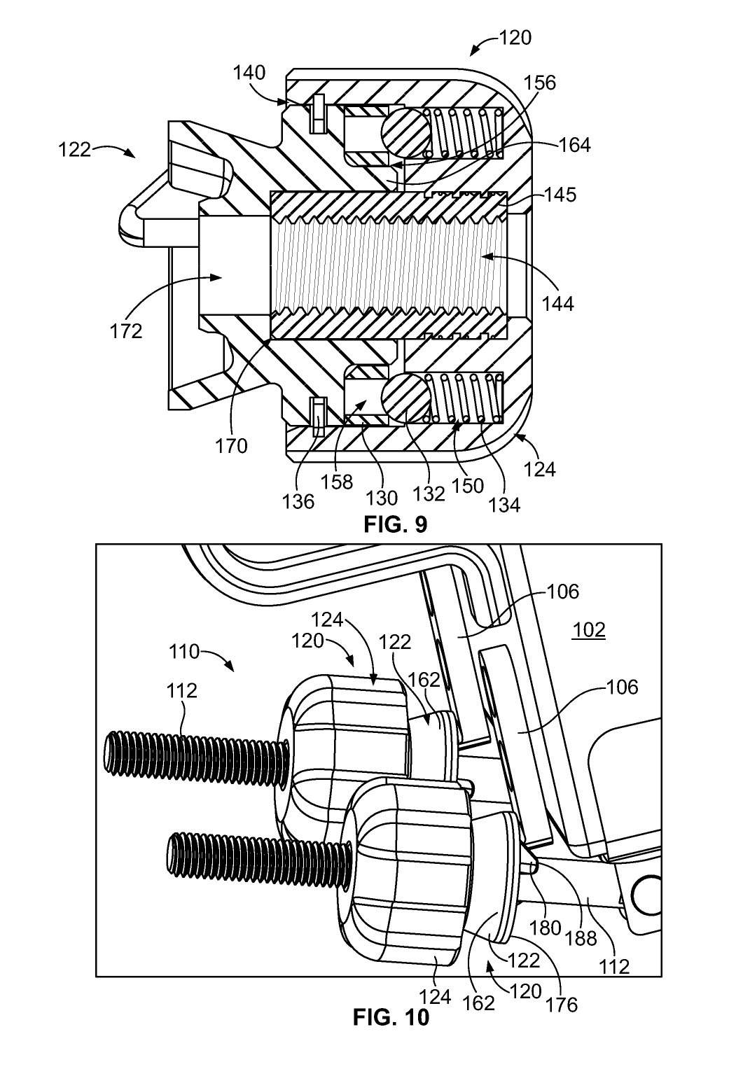

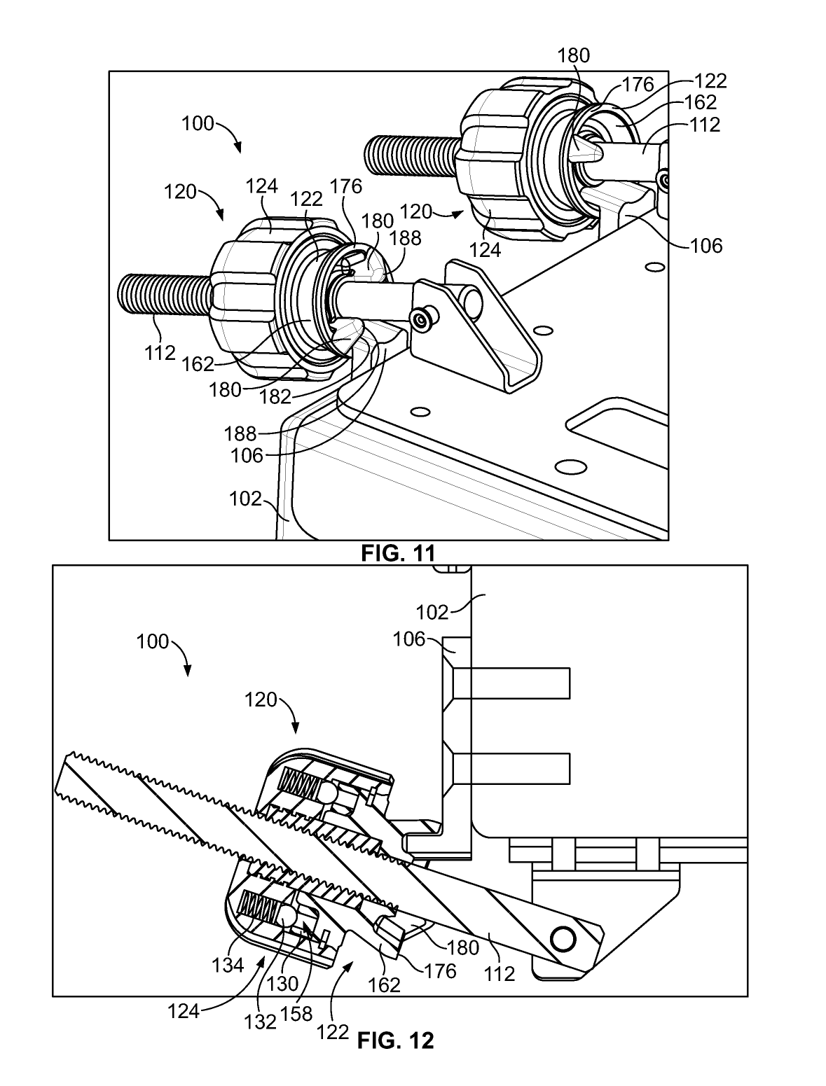

FIG. 10 is a rear perspective view of the hold down assembly 100 showing the hold down devices 120 attached to corresponding shafts 112 and engaging corresponding mounting hooks 106. FIG. 11 is a rear perspective view of the hold down assembly 100 showing the hold down devices 120 attached to corresponding shafts 112 and engaging corresponding mounting hooks 106. FIG. 12 is a cross sectional view of the hold down assembly 100 showing the hold down device 120 attached to the corresponding shaft 112 and engaging the corresponding mounting hook 106.

The locking washer 122 faces the mounting hook 106 such that the wide side 176 of the cone 162 is open to and receives the mounting hook 106. When the hold down device 120 engages the mounting hook 106, one of the tangs 180 bottoms out against the leg of the mounting hook 106. For example, the tip 188 may initially engage the mounting hook 106 as the hold down device 120 is tightened onto the shaft 112. Further tightening drives the first side 182 of the tang 180 to abut against the mounting block 106. Further rotation in a tightening direction of the locking washer 122 is blocked by the mounting hook 106. However, the actuator knob 124 is rotatable relative to the locking washer 122. The actuator knob 124 may be continued to be rotated in the tightening direction and advanced along the shaft 112, which may cause the locking washer 122 to further advance and seat on the leg of the mounting hook 106 causing the mounting hook 106 to enter the cone 162. Such further rotation of the actuator knob 124 applies a locking force through the locking washer 122 and the mounting hook 106 to the portable electronic unit 102. The actuator knob 124 may be rotated until a predetermined locking force or torque is applied. Optionally, the predetermined locking force may equate to a predetermined rotation of the actuator knob 124 after initial contact (e.g., three rotations of the actuator knob 124). Because the ratcheting does not begin to occur until the locking washer 122 engages the mounting hook 106, the number of ratcheting clicks may correspond to the amount of rotation (e.g., 6 clicks per rotation of the actuator knob 124). In other embodiments, a torque tool, such as a torque wrench may be used to achieve the desired locking force. In other embodiments, the actuator knob 124 may be rotated until hand-tight.

With reference to FIG. 12, during tightening of the hold down device 120 on the shaft 112 and prior to contact with the mounting hook 106, the biasing members 134 and ball bearings 132 are rotatably fixed in position relative to the actuator knob 124. When the hold down device 120 is freely rotated on the shaft 112 (prior to the locking washer 122 engaging the mounting hook 106), the hold down device 120 is allowed to easily move down the shaft 112. Because there is little or no resistance, the ball bearings 132 are locked in the detent holes 158 to fix the relative positions of the ratchet plate 130 and locking washer 122 relative to the actuator knob 124. No ratcheting occurs during this time, allowing the hold down device 120 to be quickly installed, which may be in contrast to conventional hold down devices that are ratcheted the entirely length of the shaft due to the ratchet plate being non-rotatable on the shaft (leading to increased assembly time and increased wear on the components such as the ball bearings, the ratchet plate and the springs).

However, once the locking washer 122 engages the mounting hook 106, the interference or resistance causes the actuator knob 124 to begin to rotate relative to the ratchet plate 130 and the locking washer 122. The actuator knob 124 is then rotatable relative to the locking washer 122 and the ratchet plate 130. For example, because the ratchet plate 130 is fixed to the locking washer 122, the actuator knob 124 and corresponding biasing members 134 and ball bearings 132 may be rotated relative to the ratchet plate 130 and the locking washer 122. As the actuator knob 124 rotates, the ball bearings 132 are transferred between the various detent holes 158 in the ratchet plate 130. The ball bearings 132 are forced out of the detent holes 158 in the ratchet plate 130 against the bias of the respective biasing members 134, and then the ball bearings 132 snap back into the next detent holes 158 that comes into registration with the ball bearings 132 due to the rotation. This snapping of the ball bearings 132 into the detent holes 158 causes an audible snap or click noise to be heard by a user as the actuator knob 124 is rotated. The ball bearings 132 and ratchet plate 130 are typically formed from a metal material such as stainless steel to cause the audible noise, however may be manufactured from other materials, such as to save weight.

The ball bearings 132 may lock or resist rotation or back-out, such as due to vibration or other forces over time. As such, the hold down device 120 resists local vibration forces without using only shaft friction to overcome the vibration to maintain the locking force without significant loosening. For example, the ball bearings 132 are forced into respective detent holes 158 in the ratchet plate 130 in the locking position of the hold down assembly 100. The biasing members 134 are designed to require a minimal force to dislodge the ball bearings 132 from the detent holes 158, but this minimal force is significant enough to resist severe vibration loadings on the hold down assembly 100. Consequently, the actuator knob 124 of the hold down assembly 100 reliably maintains a locking position on the shaft 112 despite the sometimes severe vibrations, such as occurring during flight of an aircraft. As such, the portable electronic unit 102 stays in operative communication with the other equipment in the aircraft throughout a flight.

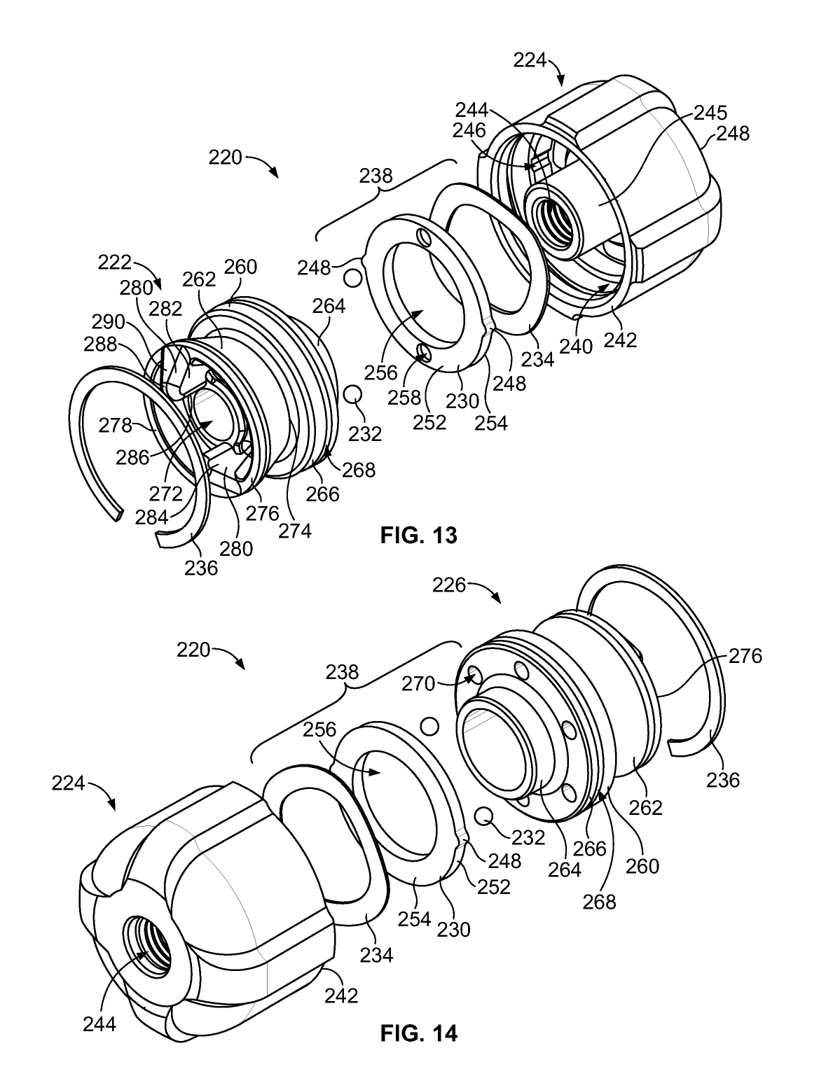

FIG. 13 is a front exploded view of a hold down assembly 200 in accordance with an exemplary embodiment. FIG. 14 is a rear exploded view of a hold down assembly 200 in accordance with an exemplary embodiment. The hold down assembly 200 is similar to the hold down assembly 100 (shown in FIG. 1) and may be used in place of the hold down assembly 100; however the hold down assembly 200 includes a different type of locking mechanism.

The hold down assembly 200 includes a hold down device 220 configured to be coupled to the shaft 112 (shown in FIG. 1). The hold down device 220 includes a locking washer 222 and an actuator knob 224 operably coupled to the shaft 112. The locking washer 222 may be similar to the locking washer 122 (shown in FIG. 1). The actuator knob 224 may be similar to the actuator knob 124 (shown in FIG. 1). In an exemplary embodiment, the hold down device 220 includes a locking mechanism 238 to lock the locking washer 222 in place and resist loosening over time, such as from vibration.

The hold down device 220 includes a ratchet plate 230, one or more ball bearings 232, one or more biasing members 234 and a clip 236 used to hold the locking washer 222, the ratchet plate 230, the ball bearings 232 and the biasing members 234 in the actuator knob 224. The ratchet plate 230, ball bearings 232 and biasing members 234 may define the locking mechanism 238 of the hold down device 220 for locking the hold down device 220 to the mounting hook 106 to resist loosening or back-out over time. In an exemplary embodiment, the ball bearings 232 are held between the ratchet plate 230 and the locking washer 222. In the illustrated embodiment, the biasing member 234 is a wave washer; however other types of biasing members may be used in alternative embodiments, such as coil springs, leaf springs, compressive gaskets, and the like.

The actuator knob 224 includes a cavity 240 configured to receive the ball bearings 232, the biasing member 234, the ratchet plate 230 and a portion of the locking washer 222. The cavity 240 is open at a front 242 of the actuator knob 224. In an exemplary embodiment, the actuator knob 224 includes a threaded bore 244 configured to be threadably coupled to the shaft 112. Optionally, the threaded bore 244 may be part of an insert 245 separate from the actuator knob 224 that is coupled to the actuator knob 224. In an exemplary embodiment, the actuator knob 224 includes pockets 246 in the cavity 240. The pockets 246 are configured to receive a portion of the ratchet plate 230. For example, the ratchet plate 230 includes protrusions 248 along the outer edge thereof that are received in the pockets 246 and held in the pockets 246. As such, the ratchet plate 230 may be fixed relative to the actuator knob 224. The ratchet plate 230 may be rotated with the actuator knob 224. The ratchet plate 230 may be rotatable relative to the locking washer 222.

The ratchet plate 230 includes a front 252 and a rear 254. The front 252 faces the locking washer 222. Optionally, the ratchet plate 230 may be generally disk shaped. The ratchet plate 230 includes a central bore 256 extending therethrough. In an exemplary embodiment, the ratchet plate 230 includes a plurality of detent holes 258 disposed about the central bore 256. The detent holes 258 are configured to receive the ball bearings 232. Optionally, the ball bearings 232 may be captured in the detent holes 258 between the front 252 of the ratchet plate 230 and the locking washer 222.

The locking washer 222 includes a base 260 and a cone 262 opposite the base 260. The cone 262 is countersunk defining a tapered collar configured to receive and lock to the mounting hook 106 (shown in FIG. 2). The base 260 is configured to be received in the actuator knob 224. In an exemplary embodiment, the base 260 includes a hub 264 configured to be received in the central bore 256 of the ratchet plate 230. The base 260 includes a flange 266 extending therefrom. The flange 266 includes a groove 268 that receives the clip 236. In an exemplary embodiment, the clip 236 does not restrict rotations such that the actuator knob 224 is rotatable relative to the locking washer 222.

In an exemplary embodiment, the base 260 includes a plurality of detent holes 270 at the rear end thereof. The detent holes 270 are disposed about the hub 264. The detent holes 270 may extend at least partially through the base 260 and may be provided in a circular pattern around the hub 264. The detent holes 270 are configured to receive the ball bearings 232 when assembled to cause a ratcheting effect during assembly and/or a locking effect when the hold down device 220 is secured to the mounting hook 106. For example, the ball bearings 232 may be rotated with the ratchet plate 230 and the actuator knob 224 to move the ball bearings 232 successively around the locking washer 222 between the detent holes 270.

The locking washer 222 includes a central bore 272, through the cone 262, which receives the shaft 112. The central bore 272 passes through the base 260 and the cone 262. Optionally, the bore 272 is sized to allow the locking washer 222 to pass freely along the shaft 112 such that the locking washer 222 is rotatable relative to the shaft 112.

The cone 262 may be similar to the cone 162 (shown in FIG. 4) and has a generally frusto-conical shape including a narrow side 274 and a wide side 276 with a lip 278 at the wide side 276. In an exemplary embodiment, the cone 262 includes one or more tangs 280 projecting into the cone 262. In an exemplary embodiment, the tangs 280 extend forward of the lip 278 of the cone 262. Each tang 280 includes a first side 282, a second side 284, an interior edge 286, a tip 288, and an angled outer wall 290. The sides 282 or 284 of the tangs 280 provide a large surface area for interfacing with the mounting hook 106.

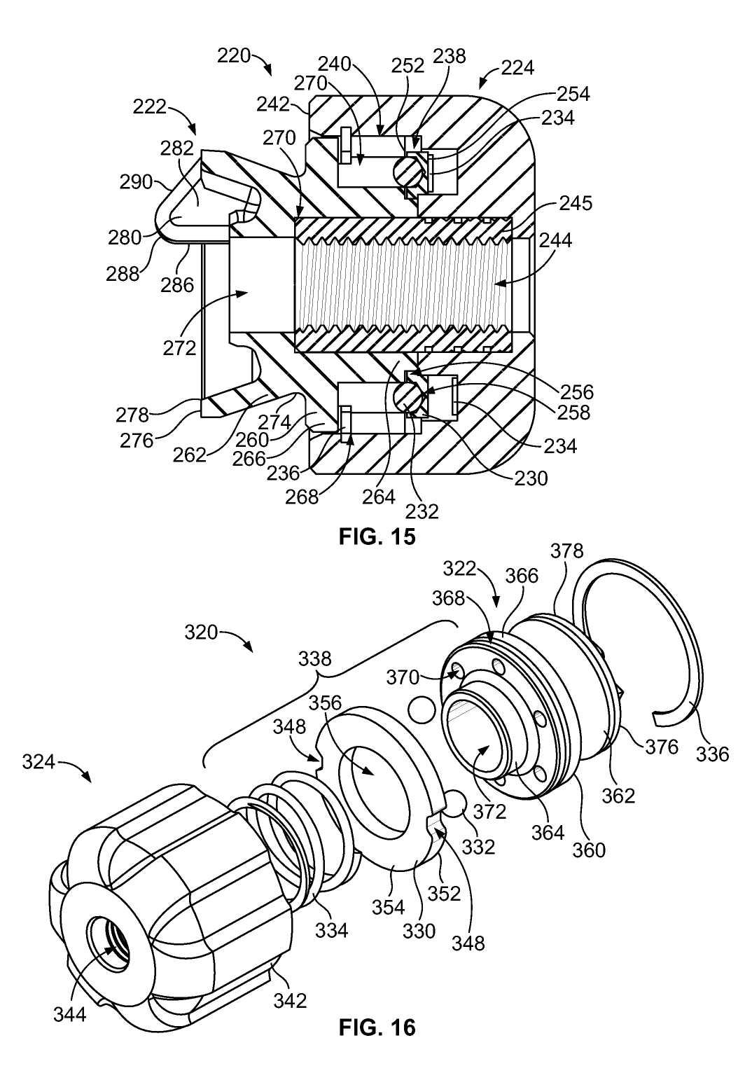

FIG. 15 is a cross-sectional view of the hold down device 220 in an assembled state. When assembled, the actuator knob 224 is coupled to the locking washer 222 and may be secured thereto to provide a unitary hold down device 220. Optionally, a portion of the locking washer 222 may be received in the actuator knob 224. A portion of the locking washer 222 may extend forward of the actuator knob 224. The actuator knob 224 is configured to be rotated to axially advance the hold down device 220 along the shaft 112 (shown in FIG. 1). The ratchet plate 230 and ball bearings 232 are received in the cavity 240 and rotatably fixed in position relative to the actuator knob 224. The biasing member 234 is positioned behind the ratchet plate 230 and biases the ratchet plate 230 forward. The ball bearings 232 are captured in the detent holes 258 of the ratchet plate 230 and are received in corresponding detent holes 270 in the locking washer 222.

During tightening of the hold down device 220 on the shaft 112 (shown in FIG. 1) and prior to contact with the mounting hook 106 (shown in FIG. 1), the locking washer 222 is rotatably fixed relative to the actuator knob 224 by the ball bearings 232. When the hold down device 220 is freely rotated on the shaft 112 (prior to the locking washer 222 engaging the mounting hook 106), the hold down device 220 is allowed to easily move down the shaft 112. Because there is little or no resistance, the ball bearings 232 are locked in the detent holes 270 to fix the relative positions of the locking washer 222 relative to the actuator knob 224. No ratcheting occurs during this time, allowing the hold down device 220 to be quickly installed

However, once the locking washer 222 engages the mounting hook 106, the interference or resistance with the locking washer 222 stops rotation of the locking washer 222 and causes the actuator knob 224 to begin to rotate relative to the locking washer 222. The ratchet plate 230 is rotated with the actuator knob 224 to rotate the ball bearings 232 to different detent holes 270 in the locking washer 222. As the actuator knob 224 rotates, the ball bearings 232 are transferred between the various detent holes 270 in the locking washer 222. The ball bearings 232 are forced out of the detent holes 270 causing the ratchet plate 230 to move rearward against the bias of the respective biasing member 234, and then the ball bearings 232 snap back into the next detent holes 270 that comes into registration with the ball bearings 232 due to the rotation. This snapping of the ball bearings 232 into the detent holes 270 causes an audible snap or click noise to be heard by a user as the actuator knob 224 is rotated. The click may be the sound of the ball bearings 232 falling into the detent holes 270 or may be the sound of the ratchet plate 230 hitting the locking washer 222. The ball bearings 232 may lock or resist rotation or back-out, such as due to vibration or other forces over time.

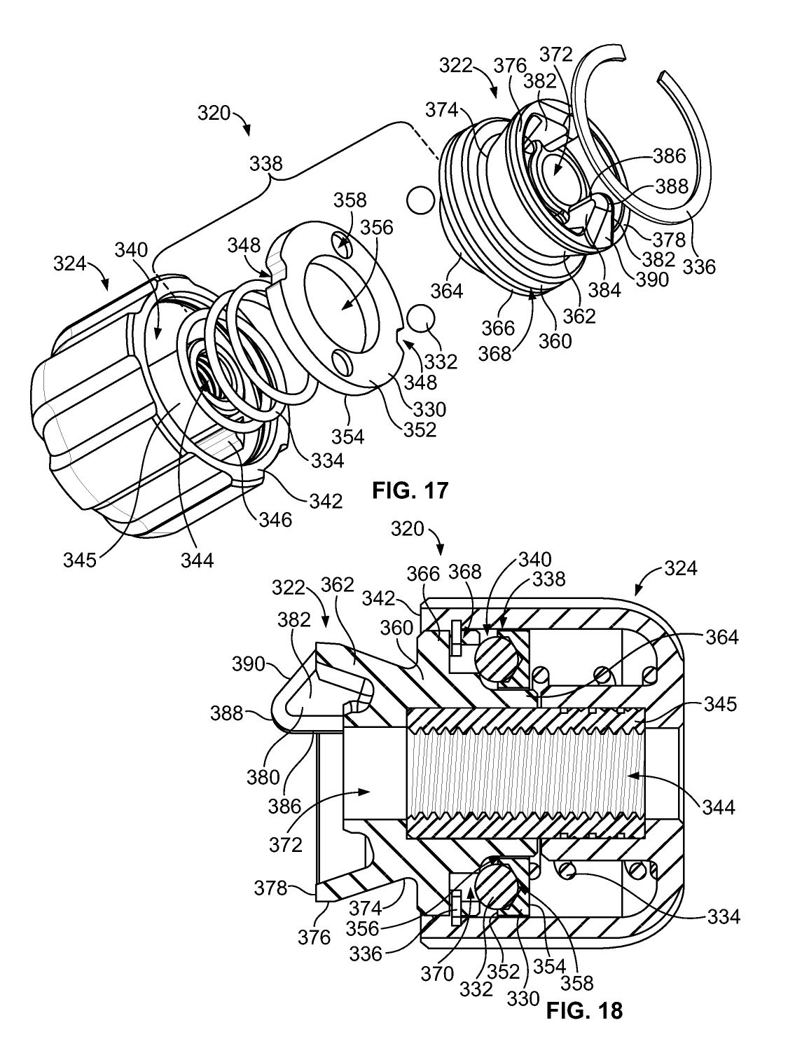

FIG. 16 is a rear exploded view of a hold down assembly 300 in accordance with an exemplary embodiment. FIG. 17 is a front exploded view of a hold down assembly 300 in accordance with an exemplary embodiment. The hold down assembly 300 is similar to the hold down assembly 100 (shown in FIG. 1) and/or the hold down assembly 200 (shown in FIG. 13) and may be used in place of the hold down assemblies 100, 200; however the hold down assembly 300 includes a different type of locking mechanism.

The hold down assembly 300 includes a hold down device 320 configured to be coupled to the shaft 112 (shown in FIG. 1). The hold down device 320 includes a locking washer 322 and an actuator knob 324 operably coupled to the shaft 112. The locking washer 322 may be similar to the locking washer 122 (shown in FIG. 1). The actuator knob 324 may be similar to the actuator knob 124 (shown in FIG. 1). In an exemplary embodiment, the hold down device 320 includes a locking mechanism 338 to lock the locking washer 322 in place and resist loosening over time, such as from vibration.

The hold down device 320 includes a ratchet plate 330, one or more ball bearings 332, one or more biasing members 334 and a clip 336 used to hold the locking washer 322, the ratchet plate 330, the ball bearings 332 and the biasing members 334 in the actuator knob 324. The ratchet plate 330, ball bearings 332 and biasing members 334 may define the locking mechanism 338 of the hold down device 320 for locking the hold down device 320 to the mounting hook 106 to resist loosening or back-out over time. In an exemplary embodiment, the ball bearings 332 are held between the ratchet plate 330 and the locking washer 322. In the illustrated embodiment, the biasing member 334 is a coil spring; however other types of biasing members may be used in alternative embodiments, such as a wave washer, leaf springs, compressive gaskets, and the like.

The actuator knob 324 includes a cavity 340 configured to receive the ball bearings 332, the biasing member 334, the ratchet plate 330 and a portion of the locking washer 322. The cavity 340 is open at a front 342 of the actuator knob 324. In an exemplary embodiment, the actuator knob 324 includes a threaded bore 344 configured to be threadably coupled to the shaft 112. Optionally, the threaded bore 344 may be part of an insert 345 separate from the actuator knob 324 that is coupled to the actuator knob 324. The biasing member 334 extends around the insert 345. For example, the biasing member 334 is concentrically, helically wound around the insert 345.

In an exemplary embodiment, the actuator knob 324 includes protrusions 346 in the cavity 340. The protrusions 346 are configured to receive a portion of the ratchet plate 330. For example, the ratchet plate 330 includes dimples 348 along the outer edge thereof that received the protrusions 346. As such, the ratchet plate 330 may be fixed relative to the actuator knob 324. The ratchet plate 330 may be rotated with the actuator knob 324. The ratchet plate 330 may be rotatable relative to the locking washer 322.

The ratchet plate 330 includes a front 352 and a rear 354. The front 352 faces the locking washer 322. Optionally, the ratchet plate 330 may be generally disk shaped. The ratchet plate 330 includes a central bore 356 extending therethrough. In an exemplary embodiment, the ratchet plate 330 includes a plurality of detent holes 358 disposed about the central bore 356. The detent holes 358 are configured to receive the ball bearings 332. Optionally, the ball bearings 332 may be captured in the detent holes 358 between the front 352 of the ratchet plate 330 and the locking washer 322.

The locking washer 322 includes a base 360 and a cone 362 opposite the base 360. The cone 362 is countersunk defining a tapered collar configured to receive and lock to the mounting hook 106 (shown in FIG. 3). The base 360 is configured to be received in the actuator knob 324. In an exemplary embodiment, the base 360 includes a hub 364 configured to be received in the central bore 356 of the ratchet plate 330. The base 360 includes a flange 366 extending therefrom. The flange 366 includes a groove 368 that receives the clip 336. In an exemplary embodiment, the clip 336 does not restrict rotations such that the actuator knob 324 is rotatable relative to the locking washer 322.

In an exemplary embodiment, the base 360 includes a plurality of detent holes 370 at the rear end thereof. The detent holes 370 are disposed about the hub 364. The detent holes 370 may extend at least partially through the base 360 and may be provided in a circular pattern around the hub 364. The detent holes 370 are configured to receive the ball bearings 332 when assembled to cause a ratcheting effect during assembly and/or a locking effect when the hold down device 320 is secured to the mounting hook 106. For example, the ball bearings 332 may be rotated with the ratchet plate 330 and the actuator knob 324 to move the ball bearings 332 successively around the locking washer 322 between the detent holes 370.

The locking washer 322 includes a central bore 372, through the cone 362, which receives the shaft 112. The central bore 372 passes through the base 360 and the cone 362. Optionally, the bore 372 is sized to allow the locking washer 322 to pass freely along the shaft 112 such that the locking washer 322 is rotatable relative to the shaft 112.

The cone 362 may be similar to the cone 162 (shown in FIG. 4) and has a generally frusto-conical shape including a narrow side 374 and a wide side 376 with a lip 378 at the wide side 376. In an exemplary embodiment, the cone 362 includes one or more tangs 380 projecting into the cone 362. In an exemplary embodiment, the tangs 380 extend forward of the lip 378 of the cone 362. Each tang 380 includes a first side 382, a second side 384, an interior edge 386, a tip 388, and an angled outer wall 390. The sides 382 or 384 of the tangs 380 provide a large surface area for interfacing with the mounting hook 106.

FIG. 18 is a cross-sectional view of the hold down device 320 in an assembled state. When assembled, the actuator knob 324 is coupled to the locking washer 322 and may be secured thereto to provide a unitary hold down device 320. Optionally, a portion of the locking washer 322 may be received in the actuator knob 324. A portion of the locking washer 322 may extend forward of the actuator knob 324. The actuator knob 324 is configured to be rotated to axially advance the hold down device 320 along the shaft 112 (shown in FIG. 1). The ratchet plate 330 and ball bearings 332 are received in the cavity 340 and rotatably fixed in position relative to the actuator knob 324. The biasing member 334 is positioned behind the ratchet plate 330 and biases the ratchet plate 330 forward. The ball bearings 332 are captured in the detent holes 358 of the ratchet plate 330 and are received in corresponding detent holes 370 in the locking washer 322.

During tightening of the hold down device 320 on the shaft 112 (shown in FIG. 1) and prior to contact with the mounting hook 106 (shown in FIG. 1), the locking washer 322 is rotatably fixed relative to the actuator knob 324 by the ball bearings 332. When the hold down device 320 is freely rotated on the shaft 112 (prior to the locking washer 322 engaging the mounting hook 106), the hold down device 320 is allowed to easily move down the shaft 112. Because there is little or no resistance, the ball bearings 332 are locked in the detent holes 370 to fix the relative positions of the locking washer 322 relative to the actuator knob 324. No ratcheting occurs during this time, allowing the hold down device 320 to be quickly installed

However, once the locking washer 322 engages the mounting hook 106, the interference or resistance with the locking washer 322 stops rotation of the locking washer 322 and causes the actuator knob 324 to begin to rotate relative to the locking washer 322. The ratchet plate 330 is rotated with the actuator knob 324 to rotate the ball bearings 332 to different detent holes 370 in the locking washer 322. As the actuator knob 324 rotates, the ball bearings 332 are transferred between the various detent holes 370 in the locking washer 322. The ball bearings 332 are forced out of the detent holes 370 causing the ratchet plate 330 to move rearward against the bias of the respective biasing member 334, and then the ball bearings 332 snap back into the next detent holes 370 that comes into registration with the ball bearings 332 due to the rotation. This snapping of the ball bearings 332 into the detent holes 370 causes an audible snap or click noise to be heard by a user as the actuator knob 324 is rotated. The click may be the sound of the ball bearings 332 falling into the detent holes 370 or may be the sound of the ratchet plate 330 hitting the locking washer 322. The ball bearings 332 may lock or resist rotation or back-out, such as due to vibration or other forces over time.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112(f), unless and until such claim limitations expressly use the phrase “means for” followed by a statement of function void of further structure.

What is claimed is:

1. A hold down assembly for an electronic unit, the hold down assembly comprising:
a locking washer having a cone at a front end thereof, the locking washer having a tang provided in the cone and extending forward from the cone, the cone being configured to receive a mounting hook of the electronic unit with a first side of the tang bearing against the mounting hook to lock the position of the locking washer relative to the mounting hook; and
an actuator knob rotatably coupled to the locking washer, the actuator knob configured to be tightened to a threaded shaft to tighten the hold down assembly to the electronic unit and drive the locking washer toward the mounting hook.

2. The hold down assembly of claim 1, wherein the cone includes a conical cavity, the tang extends into the conical cavity to engage the mounting hook.

3. The hold down assembly of claim 1, wherein the cone includes a bore extending axially therethrough configured to receive the threaded shaft, the tang extending radially outward from the bore.

4. The hold down assembly of claim 1, wherein the locking washer includes a plurality of tangs extending into the cone.

5. The hold down assembly of claim 1, wherein the cone has a lip at a forward end of the cone, the tang extending to a tip, the tip being forward of the lip.

6. The hold down assembly of claim 1, wherein the tang includes the first side and a second side opposite the first side with an interior edge therebetween, the interior edge facing the threaded shaft.

7. The hold down assembly of claim 6, wherein the first side extends between an inner surface of the cone and the interior edge.

8. The hold down assembly of claim 1, wherein the locking washer includes a base received in the actuator knob.

9. The hold down assembly of claim 1, wherein the locking washer is axially fixed to the actuator knob.

10. The hold down assembly of claim 1, wherein the locking washer includes a bore extending therethrough configured to receive the threaded shaft in a non-threaded manner.

11. The hold down assembly of claim 1, further comprising a locking mechanism for locking the locking washer to the mounting hook, the locking mechanism having a ball bearing and a ratchet plate operably receiving the ball bearings, the ball bearings being ratcheted with the ratchet plate to lock the locking washer to the mounting hook, the actuator knob receiving the locking mechanism and causing the locking mechanism to ratchet to a locked position, wherein the actuator knob, locking mechanism and locking washer are freely rotatable about the shaft until the locking washer engages the mounting hook, the locking mechanism ratcheting after the locking washer engages the mounting hook as the actuator knob is further tightened.

12. The hold down assembly of claim 1, wherein the locking washer includes a base having detent holes therein, the hold down assembly further comprising a locking mechanism for locking the locking washer to the mounting hook, the locking mechanism having a ball bearing and a ratchet plate having a detent hole receiving the ball bearing, the actuator knob receiving the locking mechanism and the locking washer with the ball bearing positioned between the ratchet plate and the base of the locking washer, the ratchet plate being fixed to the actuator knob and rotating with the actuator knob, the actuator knob being rotatably coupled to the locking washer to cause the ball bearing to successively ratchet between the detent holes of the locking washer.

13. A hold down assembly for an electronic unit, the hold down assembly comprising:
a locking washer having a cone at a front end thereof, the cone being configured to receive a mounting hook of the electronic unit to lock the position of the locking washer relative to the mounting hook;
a locking mechanism for locking the locking washer to the mounting hook, the locking mechanism having a ball bearing and a ratchet plate operably receiving the ball bearing, the ball bearing being ratcheted with the ratchet plate to lock the locking washer to the mounting hook; and
an actuator knob receiving the locking mechanism and the locking washer, the actuator knob being rotatably coupled to the locking washer, the actuator knob causing the locking mechanism to ratchet to a locked position, the actuator knob configured to be tightened to a threaded shaft to tighten the hold down assembly to the electronic unit and drive the locking washer toward the mounting hook, wherein the actuator knob, locking mechanism and locking washer are freely rotatable about the shaft until the locking washer engages the mounting hook, the locking mechanism ratcheting after the locking washer engages the mounting hook as the actuator knob is further tightened.

14. The hold down assembly of claim 13, wherein the ratchet plate includes detent holes receiving the ball bearings, the ball bearings being spring biased into the detent holes.

15. The hold down assembly of claim 13, wherein the locking washer includes detent holes receiving the ball bearings, the ratchet plate being spring biased against the ball bearings.

16. The hold down assembly of claim 13, wherein the locking washer includes a tang provided in the cone and extending forward of the cone, the tang having a first side bearing against the mounting hook to lock a position of the locking washer relative to the mounting hook.

17. The hold down assembly of claim 16, wherein the cone includes a bore extending axially therethrough configured to receive the threaded shaft, the tang extending radially outward from the bore.

18. A hold down assembly for an electronic unit, the hold down assembly comprising:
a locking washer having a base and a cone, the cone being configured to receive a mounting hook of the electronic unit to lock the position of the locking washer relative to the mounting hook, the base having detent holes therein;
a locking mechanism for locking the locking washer to the mounting hook, the locking mechanism having a ball bearing and a ratchet plate having a detent hole receiving the ball bearing; and
an actuator knob receiving the locking mechanism and the locking washer with the ball bearing positioned between the ratchet plate and the base of the locking washer, the ratchet plate being fixed to the actuator knob and rotating with the actuator knob, the actuator knob being rotatably coupled to the locking washer to cause the ball bearing to successively ratchet between the detent holes of the locking washer.

19. The hold down assembly of claim 18, wherein the locking washer includes a tang provided in the cone and extending forward of the cone, the tang having a first side bearing against the mounting hook to lock a position of the locking washer relative to the mounting hook.

20. The hold down assembly of claim 19, wherein the cone includes a bore extending axially therethrough configured to receive the threaded shaft, the tang extending radially outward from the bore.
